(19) United States
(12) Patent Application Publication
(10) Pub. No.: US 2016/0056367 A1
(43) Pub. Date: Feb. 25, 2016

(54) PIEZOELECTRIC ACTUATOR, LINEAR DRIVING DEVICE, AND ELECTRONIC APPARATUS

(71) Applicant: New Shicoh Technology Co., Ltd., Kanagawa (JP)

(72) Inventors: Junichi Tada, Kanagawa (JP); Hiroki Narushima, Kanagawa (JP)

(21) Appl. No.: 14/823,331

(22) Filed: Aug. 11, 2015

(30) Foreign Application Priority Data
Aug. 25, 2014 (JP) 2014-170247

(51) Int. Cl. H01L 41/09; G02B 13/00; G02B 7/10; H01L 41/047; H01L 41/053

(52) U.S. Cl. CPC H01L 41/09; H01L 41/0472; H01L 41/053; G02B 7/10; G02B 13/009

(57) ABSTRACT

A piezoelectric actuator, a linear driving device, and an electronic apparatus that are able to be miniaturized are provided. The piezoelectric actuator includes a vibration member in which a planar piezoelectric element and an electrode plate are affixed each other with their planar surfaces being stuck together and a driving shaft fixed to the vibration member. The vibration member has an outline having a plurality of vertexes and a plurality of sides connecting the neighboring vertexes, and the electrode plate has a connecting member for electric current which protrudes from at least one sides of the vibration member.

### CROSS REFERENCE TO RELATED APPLICATIONS

This application claims priority to Japanese Patent Application No. 2014-170247 filed on Aug. 25, 2014; and the entire contents of which are incorporated by reference herein.

### TECHNICAL FIELD

This invention relates to a piezoelectric actuator, a linear driving device, and an electronic apparatus.

### BACKGROUND ART

The publication of US patent application US2009/0159720A1 discloses a so-called bimorph type piezoelectric actuator. The bimorph type piezoelectric actuator has a vibration member in which two piezoelectric elements interposes an electrode plate. This type of the piezoelectric actuator deforms its vibration member into a bowl shape by flowing an electric current through one of or both of the piezoelectric elements via the electrode plate.

### SUMMARY

However, the vibration member disclosed in the above Patent document 1 has a circular shape, thus a connecting member for electric current disposed on the electrode plate protrudes from the circular vibration member. The piezoelectric actuator can become large in volume due to the existence of the connecting member for electric current. Thus, it is an obstacle for miniaturization of the device when the device is applied to be used in a linear driving device such as a lens driving device.

This invention aims to provide at piezoelectric actuator, a linear driving device, and an electronic apparatus that are able to be miniaturized.

One aspect of the present invention features a piezoelectric actuator including:

a vibration member in which a planar piezoelectric element and an electrode plate are affixed each other with their planar surfaces being stuck together; and

a driving shaft fixed to the vibration member; wherein

the vibration member has an outline having a plurality of vertexes and a plurality of sides connecting the neighboring vertexes, and

the electrode plate has a connecting member for electric current which protrudes from at least one sides of the vibration member.

Preferably, in the vibration member, a distance from the center of the vibration member to a distal end of the connecting member for electric current is not larger than a distance from the center of the vibration member to a vertex furthest from the center of the vibration member.

Preferably, the outline of the vibration member is a regular polygon shape.

Preferably, a plurality of connecting members for electric current are formed on the sides of the vibration member which sides do not neighbor each other, or only one connecting member for electric current is formed.

Another aspect of the present invention features a linear driving device including:

a piezoelectric actuator having a vibration member in which a planar piezoelectric element and an electrode plate are affixed each other with their planar surfaces being stuck together and a driving shaft fixed to the vibration member; and

a moving member which friction-contacts with the driving shaft of the piezoelectric actuator; wherein

the vibration member of the piezoelectric actuator has an outline having a plurality of vertexes and a plurality of sides connecting the neighboring vertexes; and

the electrode plate has a connecting member for electric current which protrudes from at least one sides of the vibration member.

Preferably, the moving member is provided with a lens.

Yet another aspect of the present invention features an electronic apparatus including:

a piezoelectric actuator having a vibration member in which a planar piezoelectric element and an electrode plate are affixed each other with their planar surfaces being stuck together and a driving shaft fixed to the vibration member;

a moving member which friction-contacts with the driving shaft of the piezoelectric actuator; and

a housing which holds the driving shaft of the piezoelectric actuator so as to vibrate therein; wherein

the vibration member of the piezoelectric actuator has an outline having a plurality of vertexes and a plurality of sides connecting the neighboring vertexes; and

the electrode plate has a connecting member for electric current which protrudes from at least one sides of the vibration member.

According to the present invention, since the connecting member for electric current protrudes from the linear side of the vibration member, thus the miniaturization can be achieved.

### BRIEF DESCRIPTION OF THE DRAWINGS

FIG. 1 shows a cross-sectional view of a linear driving device according to one embodiment of the present invention.

FIG. 2 shows a cross-sectional view along the line A-A of FIG. 1.

FIG. 3 shows a cross-sectional view of a piezoelectric actuator according to the first embodiment of the present invention.

FIG. 4 shows a perspective view of the piezoelectric actuator according to the first embodiment of the present invention.

FIG. 5 shows a perspective view of a piezoelectric actuator according to the second embodiment of the present invention.

FIGS. 6A and 6B show a plan view of the piezoelectric actuator according to the second embodiment of the present invention comparing with a comparing example in order for explanation of an installation area.

FIGS. 7A to 7C show a plan view of the piezoelectric actuator according to the second embodiment of the present invention comparing with a comparing example in order for explanation of the driving force for vibration.

FIG. 8 shows a plan view of a vibration member of the piezoelectric actuator according to the third embodiment of the present invention.

FIG. 9 shows a plan view of a vibration member of the piezoelectric actuator according to the fourth embodiment of the present invention.

FIGS. 10A to 10E show a plan views of variation examples of the vibration member of the piezoelectric actuator according to the second embodiment of the present invention.

### EXEMPLARY EMBODIMENT OF THE INVENTION

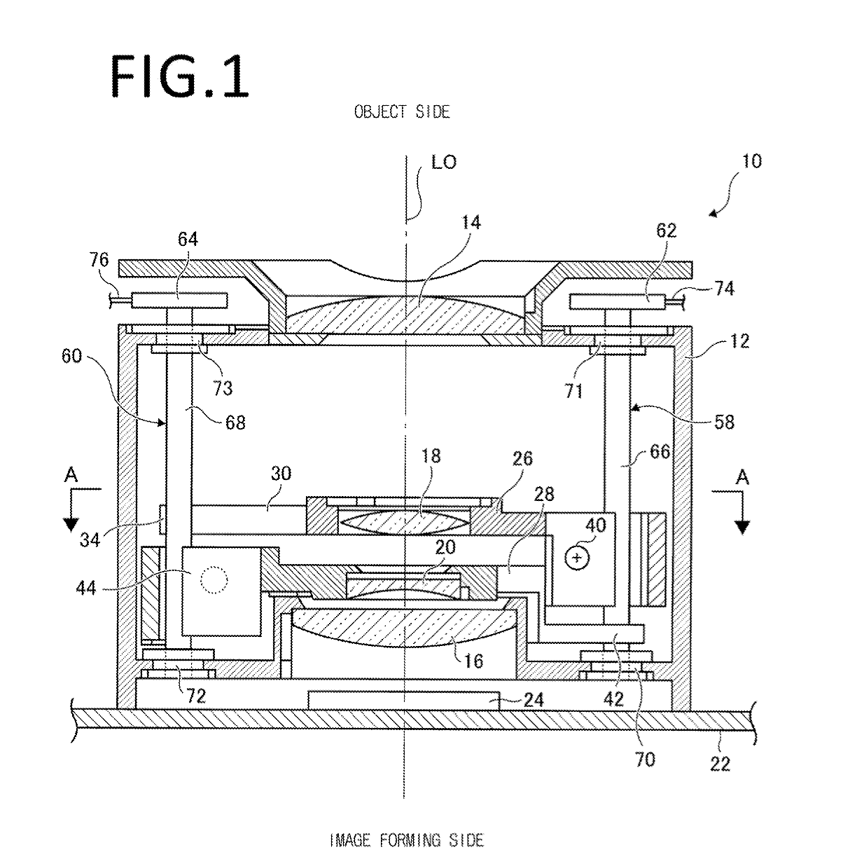

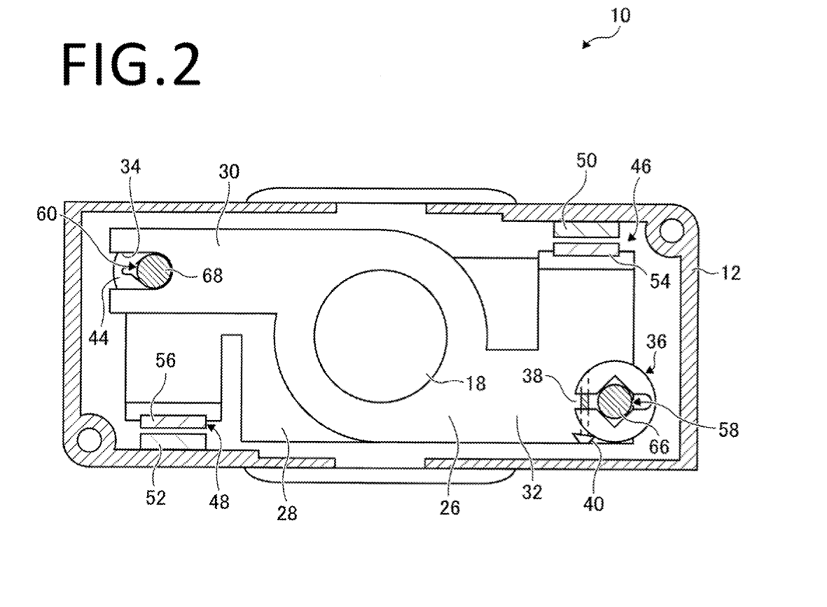

One embodiment of the present invention is described hereinafter with reference to the drawings. In FIGS. 1 and 2, a linear driving device 10 is, for example, a lens driving device. This linear driving device 10 is used in a miniaturized camera of an automatic focusing type which is installed in an electronic apparatus such as a cellular phone and a smart phone. The linear driving device 10 has a housing 12 formed as a rectangular parallelepiped shape. The housing 12 is provided with an object-side lens 14, and an image forming-side lens 16, a zoom lens 18, and a focus lens 20.

The object-side lens 14 is fixed on the top of the housing 12. The image forming-side lens 16 is fixed on the bottom of the housing 12. The image forming-side lens 16 faces toward an imaging sensor 24 disposed on a substrate 22. The housing 12 is fixed onto the substrate 22.

The zoom lens 18 is fixed by a zoom lens holder 26 which constitutes a moving member. The focus lens 20 is fixed by a focus lens holder 28 which constitutes a moving member. The object-side lens 14, the image forming-side lens 16, the zoom lens 18, and the focus lens 20 are all disposed in approximately the center of the housing 12 and on the same one optical axis LO. A light from an imaging target passes through the lenses 16 to 20 and forms an image on the imaging sensor 24.

The zoom lens holder 26, as shown in FIG. 2, has support members 30, 32 which extend into right and left directions. The distal end of one support member 30 is formed with a U-shaped engaging part 34 which engages with a driving shaft 68 of second piezoelectric actuator 60 mentioned below. Because of this configuration, the zoom lens holder 26 is guided so as not to rotate in the perpendicular direction about the optical axis LO when the zoom lens holder 26 moves in the direction along the optical axis LO.

Another support member 32 friction-contacts with a driving shall 66 of first piezoelectric actuator 58. That is to say, the distal end of the support member 32 is formed with a friction fit part 36 made of resin or metal, into which a driving shaft 66 of the first piezoelectric actuator 58 is inserted. The friction fit part 36 is formed with an opening 38 at one side of the periphery enclosing the driving shaft 66. This opening 38 is adjustable about its gap with a screw 40 so as to be adjustable about frictional or press-fit force between the friction fit part 36 and the driving shaft 66. The friction fit part 36 may be constituted by making use of elastic force of the friction fit part 36 itself to generate a predetermined friction force instead of by making use of the screw, or may be constituted by making use of a screw abutting against the driving shaft 66 to generate a friction-fit force. A half of the friction fit part 36 also may be constituted by another member, which is pressed by a spring.

The focus lens holder 28 is the same constitution with the zoom lens holder 26. More precisely, the focus lens holder 28 has an engaging part 42 and a friction fit part 44. The engaging part 42 engages with the driving shaft 66 of the first piezoelectric actuator 58 while the friction fit part 44 friction-contacts with the driving shaft 68 of the second piezoelectric actuator 60.

The housing 12 is also provided at its inside with a position sensor 46 for zoom lens 18 and a position sensor 48 for focus lens 20. Each position sensor 46, 48 has the same constitution, and is constituted by magnetic pole members 50, 52 in which the different magnetic poles, i.e. pole N and pole S are alternatively arranged along the direction of the optical axis LO of the lenses, and MR sensors 54, 56 for sensing magnetic field intensity. The MR sensor 54 is fixed to the zoom lens holder 26 while the MR sensor 56 is fixed to the focus lens holder 28. One magnetic pole member 50 is fixed to the housing 12 so as to face against the MR sensor 54 while the other magnetic pole member 52 is fixed to the housing 12 so as to face against the MR sensor 56. When the each lens holder 26, 28 moves, the movement amount and the movement direction of the each lens holder 26, 28 are detected as a change of magnetic field intensity by the MR sensors 54, 56. The MR sensors 54, 56 output signals corresponding to the detected change of magnetic field intensity.

The first piezoelectric actuator 58 and the second piezoelectric actuator 60 each has the same configuration, and each has a vibration member 62, 64 and the driving shaft 66, 68 which is fixed to the vibration member 62, 64, respectively. In this embodiment, the vibration members 62, 64 are disposed at top parts of the housing 12, and the driving shafts 66, 68 extend downward therefrom. The driving shafts 66, 68 are inserted at their lower ends into holes of receiving members 70, 72 which are provided on the housing 12 and are adhered and fixed thereto. The driving shafts 66, 68 at their proximal end parts which are proximate to the vibration members 62, 64 penetrate through holes of receiving members 71, 73 which are provided on the housing 12. The receiving members 70, 71, 72, 73 have elasticity to hold the driving shafts 66, 68 so as to vibrate therein. Each vibration members 62, 64 is connected with electric wiring 74, 76, respectively.

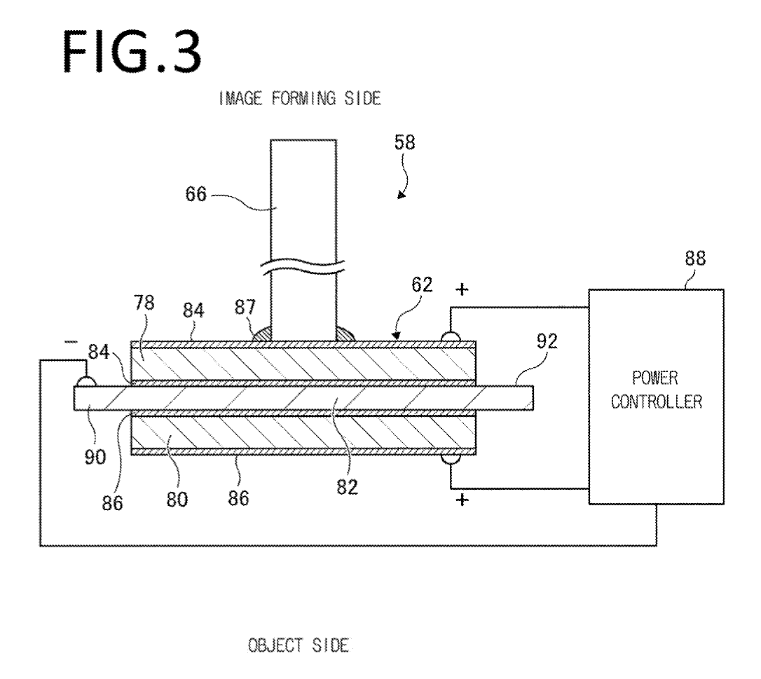

FIG. 3 shows the first piezoelectric actuator 58 which is exemplified as the piezoelectric actuator. In FIG. 3, the first piezoelectric actuator 58 is depicted as upside down about the one in FIG. 1. The first piezoelectric actuator 58 is the so-called bimorph type, and the vibration member 62 has two planar piezoelectric elements 78, 80. A planar electrode plate 82 is interposed between the piezoelectric elements 78, 80. That is to say, the piezoelectric elements 78, 80 and the electrode plate 82 are affixed each other with their planar surfaces being stuck together. The piezoelectric elements 78, 80 are formed with electrode layers 84, 86 at their upper surfaces and lower surfaces, respectively. The driving shaft 66 is affixed to one electrode layer 84 of the one piezoelectric element 78 by means of adhesive 87. The electrode plate 82 is made of a material having elasticity such as a metal plate. It is preferable that the external outlines of piezoelectric elements 78, 80 and the external outlines of electrode plate 82 are almost the same in regard to their shapes and their dimensions except for the connecting member for electric current as described below. Specifically, it is preferable that the piezoelectric elements 78, 80 do not extend beyond the outer peripheral of the electrode plate 82. It may be possible that the electrode layer 84 is formed with a hole, through which hole the driving shaft 66 is directly coupled to the piezoelectric element 78. It also may be possible that the entire structure of the piezoelectric element 78 including the electrode layer 84 is formed with a hole, through which hole the driving shaft 66 is directly coupled to the electrode plate 82. Further, it also may be possible that the entire structure of the vibration member is formed with a hole, through which hole the outer circumference surface of the driving shaft 66 is directly coupled to the inner surface of the hole in the vibration member 62.

The electrode layers 84, 86 exposed to the surface of the vibration member 62 are connected, for example, to the positive electrode of a power controller 88 while the electrode plate 82 is connected to the negative (ground) electrode of the power controller 88. When a pulse voltage is repeatedly applied between the first electrode layer 84 and the electrode plate 82, the electric current flows through the first piezoelectric element 78 to make it expand or contract, thus the vibration member 62 repeatedly deforms itself into a bowl shape in one direction and back quickly to the original shape due to the elasticity of the electrode plate 82. Accompanying with this deformation, the driving shaft 66 is also repeatedly shifted into and back to the axis direction in a minute amount. When a pulse voltage is repeatedly applied between the second electrode layer 86 and the electrode plate 82, the electric current flows through the second piezoelectric element 80 to make it expand or contract, thus the vibration member 62 repeatedly deforms itself into an inverted bowl shape and back quickly to the original shape due to the elasticity of the electrode plate 82. Accompanying with this deformation, the driving shaft 66 is also repeatedly shifted into and back to the axis direction in a minute amount.

Now, a movement of the zoom lens holder 26 by making use of the first piezoelectric actuator 58 is described hereinafter. As already mentioned, when the pulse voltage is repeatedly applied to the first piezoelectric actuator 58, the vibration member 62 deforms itself into the bowl shape in one direction and back quickly to the original shape. Accompanying with this deformation, the driving shaft 66 is also repeatedly shifted into and back to the axis direction in a minute amount. When the vibration member 62 is deformed into the bowl shape in one direction, since the friction fit part 36 of the zoom lens holder 26 is frictionally contacted with the driving shaft 66 of the first piezoelectric actuator 58, thus the zoom lens holder 26 moves along with the driving shaft 66. On the other hand, when the vibration member 62 is quickly deformed back to the original planar shape, the driving shaft 66 moves into the reverse direction very quickly. However, the zoom lens holder 26 cannot follow the movement of the driving shaft 66 due to the high-speed movement, thus the zoom lens holder 26 does not move back to the original position but remains at the place. Therefore, the zoom lens holder 26, while one cycle of the vibration, moves in the extent corresponding to the magnitude of the amplitude of the deformation of the vibration member 62. By repeatedly applying the pulse voltage to generate such movement repeatedly, the zoom lens holder 26 can be moved to a desired position.

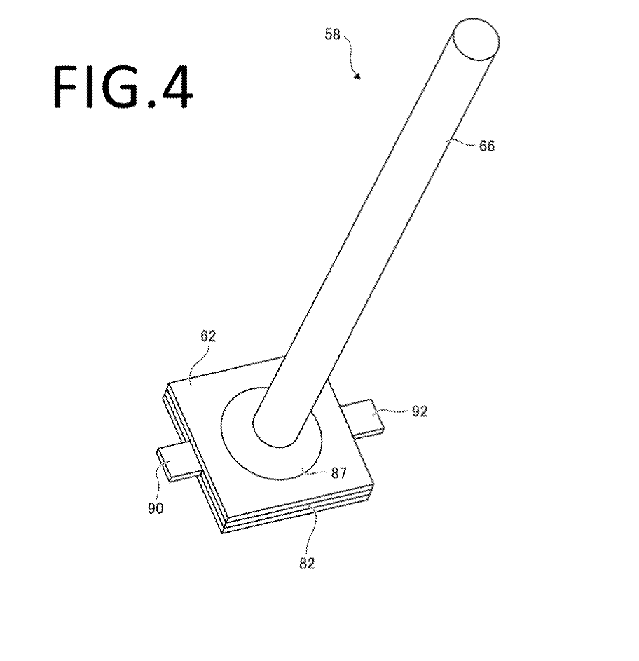

FIG. 4 shows a perspective view according to the first embodiment of the piezoelectric actuator 58. As shown in FIG. 4, the outer shape of the vibration member 62 of the piezoelectric actuator 58 is, for example, a square having four vertexes and four sides each of which sides connects the neighboring vertexes. The one of the sides of the vibration member 62 is formed at its center with a first connecting member 90 for electric current in a protruded manner which is integrally formed with the above-mentioned electrode plate 82. Another side opposing to the above one side is formed at its center with a second connecting member 92 for electric current in a protruded manner which is also integrally formed with the electrode plate 82. Any one of or both of the first connecting member 90 and the second connecting member 92 for electric current is/are connected with one end of the connecting wire(s) 72 for electric current.

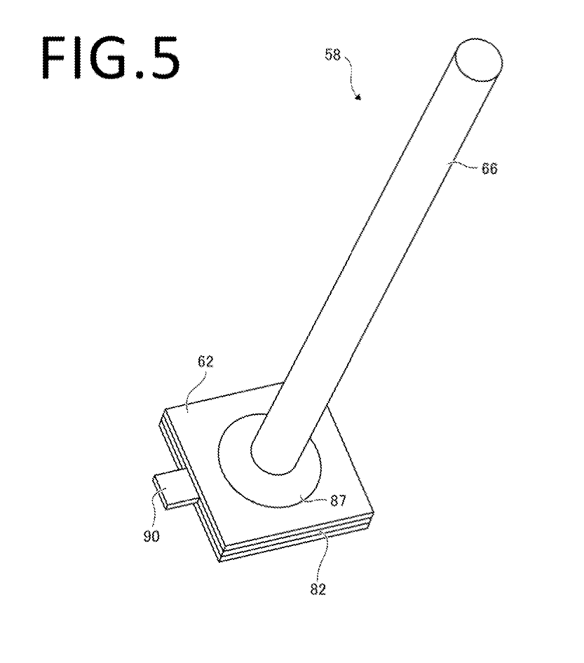

FIG. 5 shows a perspective view according to the second embodiment of the piezoelectric actuator 58. In the second embodiment, the connecting member 90 for electric current is formed at the center of only one side of the vibration member 62 in a protruded manner. In the previous first embodiment, since the connecting members 90, 92 for electric current are formed on the opposing two sides, thus the vibration member 62 is easy to symmetrically deform, and can keep an excellent balance during the vibration. On the other hand, in the second embodiment, since the size, in overall, of the connecting member for electric current can be small comparing with the one in the first embodiment, the driving force of the vibration can be increased.

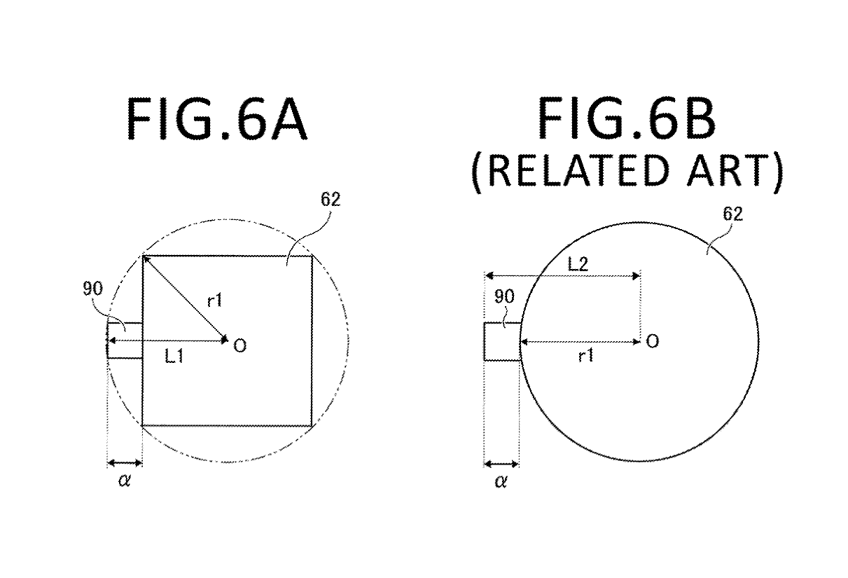

As shown in FIG. 6A, when the length of the protruded part of the connecting member 90 for electric current is α, and the distance from the center of the vibration member 62 to the vertex, is r1, then the distance L1 from the center O of the vibration member 62 to the distal end of the connecting member 90 for electric current is shown by the following formula (1).

L1=r1/√2+α (1)

Here, the α is selected so as to meet the condition: L1≦r1.

In other words, since r1/√2+α≦r1, an inequality α≦r1−r1/√2 is established. In contrast, as shown in FIG. 6B, if the outer shape of the vibration member 62 is a circular shape, the distance L2 from the center of the vibration member 62 to the distal end of the connecting member 90 for electric current is shown by the following formula (2).

L2=r1+α (2)

Comparing the formula (1) with the formula (2), it can be noted that L1 is dearly smaller than L2. Therefore, the vibration member 62 of the second embodiment in which the outer shape is a square has a smaller occupation area than the one in the comparing example in which the outer shape is a circular shape.
Further, in the case that the outer shape of the vibration member 62 is a rectangular shape, and if the housing 12 has a rectangular parallelepiped shape, as described above, a corner of the vibration member 62 is just fitted within a corner of the housing 12, thus the piezoelectric actuator 58 can be well accommodated in the housing 12.

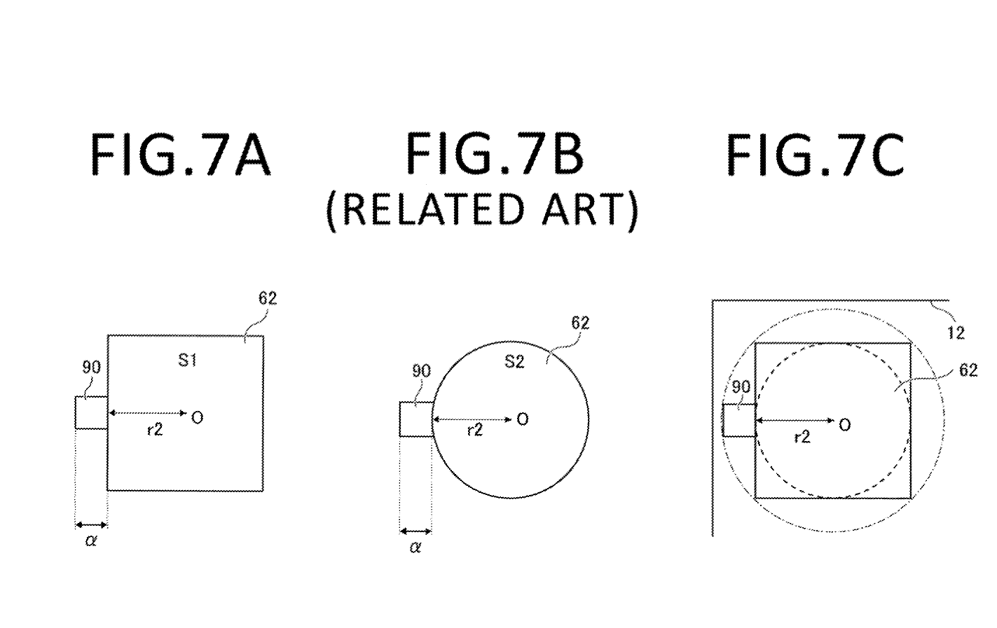

FIG. 7 shows several examples for comparing with each other in which the distance from the each center O to the each distal end of the connecting member 90 for electric current is the same distance of “r2+α”.

In the second embodiment shown in FIG. 7A, the vibration member is a square shape, thus the area S1 of the vibration member 62 is shown by the following formula (3).

S1=4r2² (3)

In the comparative example shown in FIG. 7B, the vibration member 62 is a circular shape, thus the area S2 of the vibration member 62 is shown by the following formula (4).

S2=πr2² (4)

Based on the above formulas (3) and (4), an inequality S1>S2 is established.
In the piezoelectric actuator 58, the driving force by vibration of the vibration member 62 is deemed to be proportional to the area of the vibration member 62 if the piezoelectric element is made of the same material and has the same thickness and the same alignment characteristic. Therefore, the driving force by vibration of the vibration member 62 in the second embodiment is larger than the one in the comparative example. The linear driving device 10 is easy to manufacture, when the vibration member 62 is assembled into the corner of the rectangular-parallelepiped housing 12, if the connecting member 90 for electric current is allowed to be assembled in the housing 12 in any position (or any orientation). By that case, since the area of the vibration member 62 of the second embodiment which is shown by the solid line in FIG. 7C come to be larger than the area of the vibration member 62 of the comparative example which is shown by the dotted line in FIG. 7C when they occupy the same installation area, thus the driving force in the second embodiment can be larger.

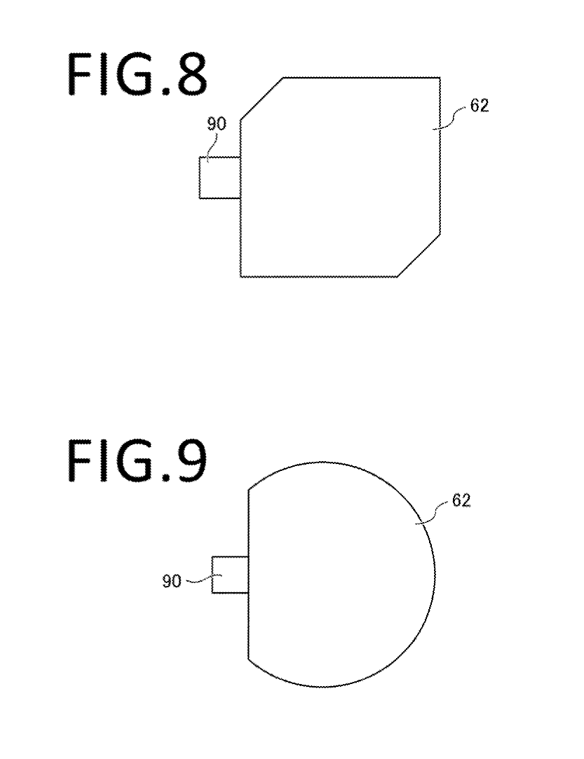

In the present invention, the outer shape of the vibration member 62 is not limited to the square shape, but may be other regular polygons. Further, the outer shape of the vibration member 62 is not limited to the regular polygons, but may be a shape in which one part of a square shape is cut off as in the third embodiment shown in FIG. 8. Further, it may be possible that one part of a circular shape is cut off to make a linear side to which side the connecting member 90 for electric current is coupled as in the fourth embodiment shown in FIG. 9.

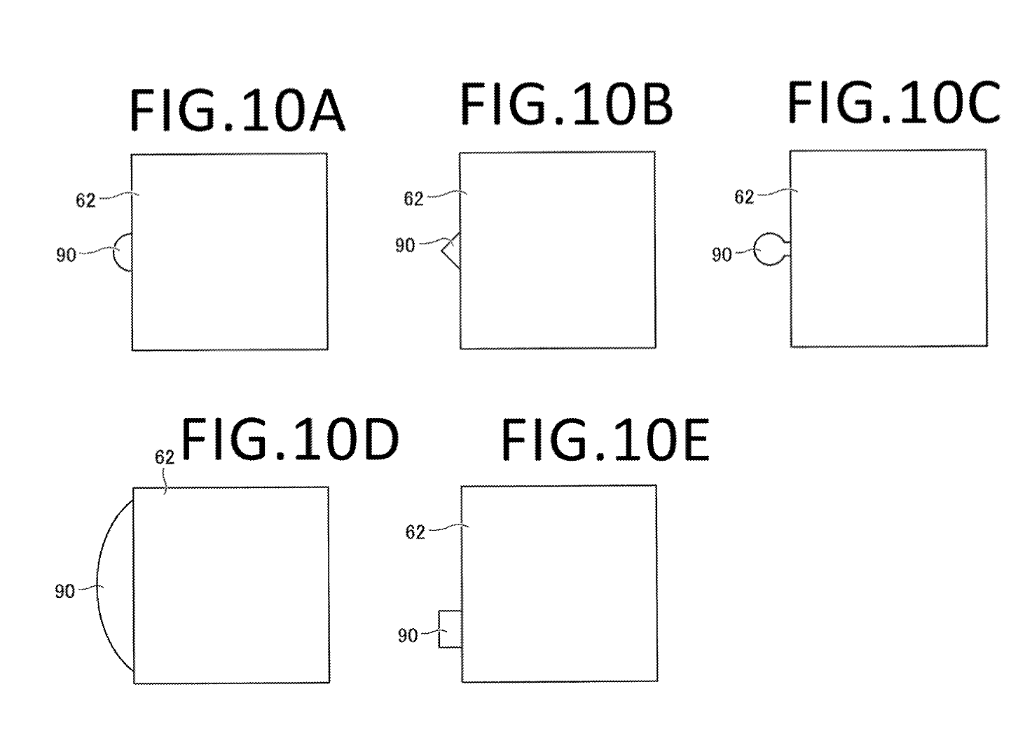

Further, the connecting member 90 for electric current is not limited to the rectangular shape but can be formed as other different shapes as shown in FIG. 10. For example, the connecting member 90 for electric current can be formed as a semicircular shape as shown in FIG. 10A, or as a triangular shape as shown in FIG. 10B. The connecting member 90 for electric current can be formed so that the proximal end of the connecting member 90 is thinned while the other end part to which one end of the electric wiring 74 is connected by solder welding is enlarged. In this case, since the vibration of the vibration member 62 is less affected if the width of the boundary portion between the electrode plate 82 itself and the connecting member 90 for electric current is small, the driving force generated by the vibration member 62 can be increased. Conversely, as shown in FIG. 10D, the connecting member 90 for electric current can be protruded from the one entire side of the vibration member 62. This configuration can be disadvantageous for the enhancement of the driving force but can make the connection operation easy. Further, as shown FIG. 10E, the connecting member 90 for electric current can be protruded not from the center of the side of the vibration member 62 but from a deviated portion from the center of the vibration member 62.

In the above description, the vibration member of the piezoelectric actuator is explained as of bimorph type. However, the so-called unimorph type may be also employed as the vibration member where one planer piezoelectric element and one electrode plate are affixed each other with their planer surfaces being stuck together. In this case, since the surface of the electrode plate opposite to the piezoelectric element is not necessarily to connect to the wiring for electric current, unevenness of vibration of the vibration member can be reduced. Further, the vibration member may be a structure in which piezoelectric elements and electrode plates are alternatively stacked in several times.

What is claimed is:

1. A piezoelectric actuator comprising:
a vibration member in which a planar piezoelectric element and an electrode plate are affixed each other with their planar surfaces being stuck together; and
a driving shaft fixed to the vibration member; wherein
the vibration member has an outline having a plurality of vertexes and a plurality of sides connecting the neighboring vertexes, and
the electrode plate has a connecting member for electric current which protrudes from at least one sides of the vibration member.

2. The piezoelectric actuator according to claim 1, wherein in the vibration member, a distance from the center of the vibration member to a distal end of the connecting member for electric current is not larger than a distance from the center of the vibration member to a vertex furthest from the center of the vibration member.

3. The piezoelectric actuator according to claim 1, wherein the outline of the vibration member is a regular polygon shape.

4. The piezoelectric actuator according to claim 2, wherein the outline of the vibration member is a regular polygon shape.

5. The piezoelectric actuator according to claim 1, wherein a plurality of connecting members for electric current are formed on the sides of the vibration member which sides do not neighbor each other.

6. The piezoelectric actuator according to claim 2, wherein at plurality of connecting members for electric current are formed on the sides of the vibration member which sides do not neighbor each other.

7. The piezoelectric actuator according to claim 1, wherein only one connecting member for electric current is formed.

8. The piezoelectric actuator according to claim 2, wherein only one connecting member for electric current is formed.

9. A linear driving device comprising:
a piezoelectric actuator which includes:
a vibration member in which a planar piezoelectric element and an electrode plate are affixed each other with their planar surfaces being stuck together; and
a driving shaft fixed to the vibration member; and
a moving member which friction-contacts with the driving shaft of the piezoelectric actuator; wherein
the vibration member of the piezoelectric actuator has an outline having a plurality of vertexes and a plurality of sides connecting the neighboring vertexes, and
the electrode plate has a connecting member for electric current which protrudes from at least one sides of the vibration member.

10. The linear driving device according to claim 9, wherein the moving member is provided with a lens.

11. An electronic apparatus comprising:
a piezoelectric actuator which includes:
a vibration member in which a planar piezoelectric element and an electrode plate are affixed each other with their planar surfaces being stuck together; and
a driving shaft fixed to the vibration member;
a moving member which friction-contacts with the driving shaft of the piezoelectric actuator; and
a housing which holds the driving shaft of the piezoelectric actuator so as to vibrate therein; wherein
the vibration member of the piezoelectric actuator has an outline having a plurality of vertexes and a plurality of sides connecting the neighboring vertexes, and
the electrode plate has a connecting member for electric current which protrudes from at least one sides of the vibration member.
